(19) United States
(12) Patent Application Publication
(10) Pub. No.: US 2005/0142715 A1
(43) Pub. Date: Jun. 30, 2005

(54) Semiconductor device with high dielectric constant insulator and its manufacture

(75) Inventors: Tsunehisa Sakoda, Kawasaki (JP); Yoshihiro Sugiyama, Kawasaki (JP); Masaomi Yamaguchi, Kawasaki (JP); Hiroshi Minakata, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 10/973,449

(22) Filed: Oct. 27, 2004

(30) Foreign Application Priority Data
Dec. 26, 2003 (JP) 2003-432555
Dec. 26, 2003 (JP) 2003-431910
Aug. 18, 2004 (JP) 2004-238211

(51) Int. Cl. H01L 21/8242

(52) U.S. Cl. 438/197

(57) ABSTRACT

A semiconductor device has: a silicon substrate; a silicon oxide layer formed on the surface of the silicon substrate; a high dielectric constant insulating film including a first oxide layer formed above the silicon oxide layer and made of a high dielectric constant film having a dielectric constant higher than silicon oxide and a first nitride layer formed above the first oxide layer and made of nitride having an oxygen intercepting capability, or a high dielectric constant insulating film including a first oxide film formed on the silicon oxide layer, a second oxide layer formed on the first oxide layer and a third oxide layer formed on the second oxide layer, the first and third oxide layers having an oxygen diffusion coefficient smaller than the second oxide layer; and a gate electrode formed on the high dielectric constant insulating layer and made of oxidizable material.

### CROSS REFERENCE TO RELATED APPLICATION

This application is based on and claims priorities of Japanese Patent Applications No. 2003-432555 filed on Dec. 26, 2003, No. 2003-431910 filed on Dec. 26, 2003 and No. 2004-238211 filed on Aug. 18, 2004, the entire contents of which are incorporated herein by reference.

### BACKGROUND OF THE INVENTION

A) Field of the Invention

The present invention relates to a semiconductor device and its manufacture method, and more particularly to a semiconductor device having a high dielectric constant oxide insulating film and its manufacture method.

B) Description of the Related Art

As representative semiconductor elements used in a semiconductor integrated circuit device, insulated gate (IG) type field effect transistors (FET) typically MOS transistors are widely used. For high integration of semiconductor integrated circuit devices, IG-FETs have been miniaturized based upon the scaling rules. Miniaturization reduces the size of IG-FET, such as thinning a gate insulating film and elongating a gate length, to improve the characteristics of the miniaturized IG-FET and maintain the characteristics in a normal state.

The thickness of a gate oxide film of the next generation MOS transistor is required to be thinned to 2 nm or thinner. At such a thickness, tunnelling current starts flowing directly through the gate oxide film, resulting in an increase in gate leak current and consumption power. Miniaturization has a limit so long as silicon oxide is used as the gate insulating film. In order to suppress the tunneling current flowing through the gate oxide film, it is desired to form a thick gate insulating film.

In order to increase the physical film thickness while the thickness of a gate insulating film is maintained at 2 nm or thinner when converted to a silicon oxide converted film thickness (capacitor equivalent thickness, CET), it has been proposed to use insulator having a dielectric constant higher than that of silicon oxide, as the material of a gate insulating film. It is said that the dielectric constant of silicon oxide is about 3.5 to 4.5 (e.g., 3.9) and that of nitride silicon is about 7 to 8 (e.g., 7.5) higher than the silicon oxide, although the dielectric constant changes with a film forming method.

Japanese Patent Laid-open Publication No. 2001-274378 proposes to use insulators having a dielectric constant higher than that of silicon oxide as the material of a gate insulating film, such insulators including: barium (strontium) titanate (Ba(Sr)TiO₃ having a dielectric constant of 200 to 300; titanium oxide (TiO₂) having a dielectric constant of about 60; tantalum oxide (Ta₂O₅), zirconium oxide (ZrO₂) and hafnium oxide (HfO₂) respectively having a dielectric constant near at 25; silicon nitride (Si₃N₄) having a dielectric constant of about 7.5; and alumina (Al₂O₃) having a dielectric constant of about 7.8. It also proposes the structure that a silicon oxide film is interposed between the high dielectric constant film made of one of these insulators and a silicon substrate.

As a new material having a high dielectric constant is adopted as the material of a gate insulating film of IG-FET, a new problem occurs. Zirconium oxide and hafnium oxide are likely to be crystallized during a high temperature process, and leak current increases because of electric conduction via crystal grain boundaries and defect energy levels.

Japanese Patent Laid-open Publication No. 2001-77111 proposes to add aluminum oxide to zirconium oxide and hafnium oxide to hinder the generation of a crystal structure and maintain an amorphous phase.

Japanese Patent Laid-open Publication No. 2003-8011 proposes to add silicon oxide to hafnium oxide to increase the thermal stability of hafnium oxide in the amorphous phase.

Japanese Patent Laid-open Publication No. 2003-23005 indicates that as a high dielectric constant material (High-k material) layer made of a metal oxide film is formed on a silicon substrate, a silicon oxide layer is formed at the interface between the metal oxide film and silicon substrate so that the effective dielectric constant lowers, and proposes to flow hydrogen instead of oxygen, before the metal oxide film is formed.

Japanese Patent Laid-open Publication No. 2002-359370 proposes to form a nitrogen atom layer on both sides of a high dielectric constant gate insulating film in order to suppress diffusion of impurities from a gate electrode to a silicon substrate and diffusion of metal elements and oxygen from a gate insulating film to a gate electrode or a silicon substrate.

### SUMMARY OF THE INVENTION

An object of this invention is to provide a semiconductor device having a novel gate insulating film structure.

Another object of this invention is to provide a semiconductor device having a gate insulating film made of insulating material having a dielectric constant higher than that of silicon oxide.

Still another object of this invention is to provide a semiconductor device-using a high dielectric constant oxide film as a gate insulating film and reducing a shift in a flat band voltage and reducing hysteresis.

Another object of the present invention is to provide a semiconductor device having a gate insulating film containing high dielectric constant oxide insulating material having a dielectric constant higher than silicon oxide, the semiconductor device capable of suppressing an increase in CET and hysteresis and a shift of a flat band voltage or threshold value.

Another object of the present invention is to provide a semiconductor device manufacture method capable of forming a gate insulating film containing high dielectric constant insulating material having a dielectric constant higher than silicon oxide.

Another object of the present invention is to provide a semiconductor device manufacture method capable of forming a gate insulating film including a high dielectric constant insulating film, with a suppressed flat band voltage shift and a reduced hysteresis.

According to one aspect of the present invention, there is provided a semiconductor device comprising: a silicon substrate; a silicon oxide layer formed on a surface of the silicon substrate; a first oxide layer formed above the silicon oxide layer, the first oxide layer being made of a high dielectric constant film having a dielectric constant higher than silicon oxide; a first nitride layer formed above the first oxide layer, the first nitride layer being made of nitride having an oxygen intercepting capability; and a gate electrode formed above the first nitride layer.

The following phenomenon has been found. When a high dielectric constant oxide film is formed on the underlying silicon oxide layer by thermal CVD and an oxidizable conductive layer is stacked on the high dielectric constant oxide film to form an insulated gate electrode and if a nitride layer having an oxygen intercepting capability is formed under the gate electrode, a gate insulating film can be formed which suppresses the formation of a reaction layer and has a reduced flat band voltage shift and a small hysteresis.

According to another aspect of the present invention, there is provided a semiconductor device comprising: a silicon substrate; a silicon oxide layer formed on a surface of the silicon substrate; a high dielectric constant insulating layer including a first oxide layer formed above the silicon oxide layer, a second oxide layer formed on the first oxide layer and a third oxide layer formed on the second oxide layer, the first and third oxide layers having an oxygen diffusion coefficient smaller than the second oxide layer; and a gate electrode formed above the high dielectric constant insulating layer.

According to another aspect of the present invention, there is provided a method of manufacturing a semiconductor device comprising steps of: (a) removing a natural oxide film on a surface of a silicon substrate by wet etching; (b) forming an underlying silicon layer on the surface of the silicon substrate with the natural oxide film being removed, by a chemical process; (c) forming a first high dielectric constant oxide layer on the underlying silicon layer by CVD at a first oxygen supply rate; (d) forming a second high dielectric constant oxide layer on the first high dielectric constant oxide layer by CVD at a second oxygen supply rate higher than the first oxygen supply rate; (e) forming a third high dielectric constant oxide layer on the second high dielectric constant oxide layer by CVD at a third oxygen supply rate lower than the second oxygen supply rate; and (f) forming a gate electrode on the third high dielectric constant oxide layer by using oxidizable material.

The following phenomenon has been found. When a high dielectric constant insulating film having a dielectric constant higher than silicon oxide is formed on the underlying silicon oxide layer by thermal CVD and if the oxygen amount in film forming source gasses is suppressed at the growth start and end stages and is set sufficiently at the growth middle stage, a gate insulating film can be formed which has a reduced flat band voltage shift and a small hysteresis.

It is said that the flat band voltage changes with fixed charges and the hysteresis changes with trap levels. It can be considered that by suppressing the oxygen supply amount in film forming source gasses at the growth start and end stages, it is possible to suppress the formation of a reaction layer at the interface between the high dielectric constant insulating layer and an adjacent layer and the generation of fixed charges, and by supplying a sufficient oxygen amount at the growth middle stage, it is possible to suppress the formation of trap levels in the film and reduce the hysteresis.

### BRIEF DESCRIPTION OF THE DRAWINGS

FIGS. 1A to 1H are cross sectional views illustrating a method of forming a high dielectric constant insulating film on a silicon substrate by chemical vapor deposition (CVD).

FIGS. 2A and 2B are a schematic block diagram showing the structure of a thermal CVD system and a table summarizing experiment conditions.

FIGS. 3A to 3E are cross sectional views of sample MOS structures and a table showing film thicknesses of the samples S1 and S3.

FIGS. 4A and 4B are graphs summarizing leak currents of the samples and a relation between flat band voltage shift amount ΔVfb and hysteresis.

FIGS. 5A and 5B are cross sectional views showing the structure of a gate insulating film and a MOS transistor according to an embodiment.

FIGS. 6A to 6H are cross sectional views illustrating a method of forming a high dielectric constant insulating film on a silicon substrate by chemical vapor deposition (CVD).

FIGS. 7A and 7B are a schematic block diagram showing the structure of a thermal CVD system and a table summarizing experiment conditions.

FIGS. 8A, 8B and 8C are graphs showing the C-V characteristics of manufactured MOS structures.

FIG. 9 is a graph summarizing a relation between a flat band voltage shift amount ΔVfb and a hysteresis.

FIGS. 10A and 10B are cross sectional views showing the structure of a MOS transistor according to an embodiment.

FIGS. 11A to 11H are cross sectional views showing the structures of samples and a table showing the EOT measurement results.

FIGS. 12A and 12B are graphs showing the measurement results of the drain current—gate voltage characteristics and simulation results.

FIG. 13 is a cross sectional view showing the structure of a semiconductor integrated circuit device.

FIG. 14 is a cross sectional view showing the structure of a semiconductor integrated circuit device.

### DESCRIPTION OF THE PREFERRED EMBODIMENTS

Hafnium oxide (hafnia) is insulator capable of providing a dielectric constant higher than silicon oxide by several to several tens times, and is highly expected as the gate insulating film of IG-FET. Thermal chemical vapor deposition (CVD) is known as a method capable of forming an oxide insulating film having a high dielectric constant such as hafnium oxide, with a good film quality and without adversely affecting the substrate.

As a silicon oxide layer is formed on the surface of a silicon substrate and a hafnium oxide film and a polysilicon film are formed on the silicon oxide film by thermal CVD to form an insulated gate structure, a flat band voltage shifts. It is therefore possible to control the threshold voltage. Since the oxide film between the hafnium oxide film and silicon substrate becomes thick, CET increases.

The present inventors presume that a reaction layer grows at the interface between a hafnium oxide film and a polysilicon layer and at other positions so that fixed charges are generated. The present inventors tried to suppress reaction at the interface with the polysilicon layer by covering the surface of the hafnium oxide film with another film. As the reaction suppressing film, an AlN film was first tried. In the following, description will be made along with the experiments made by the present inventors.

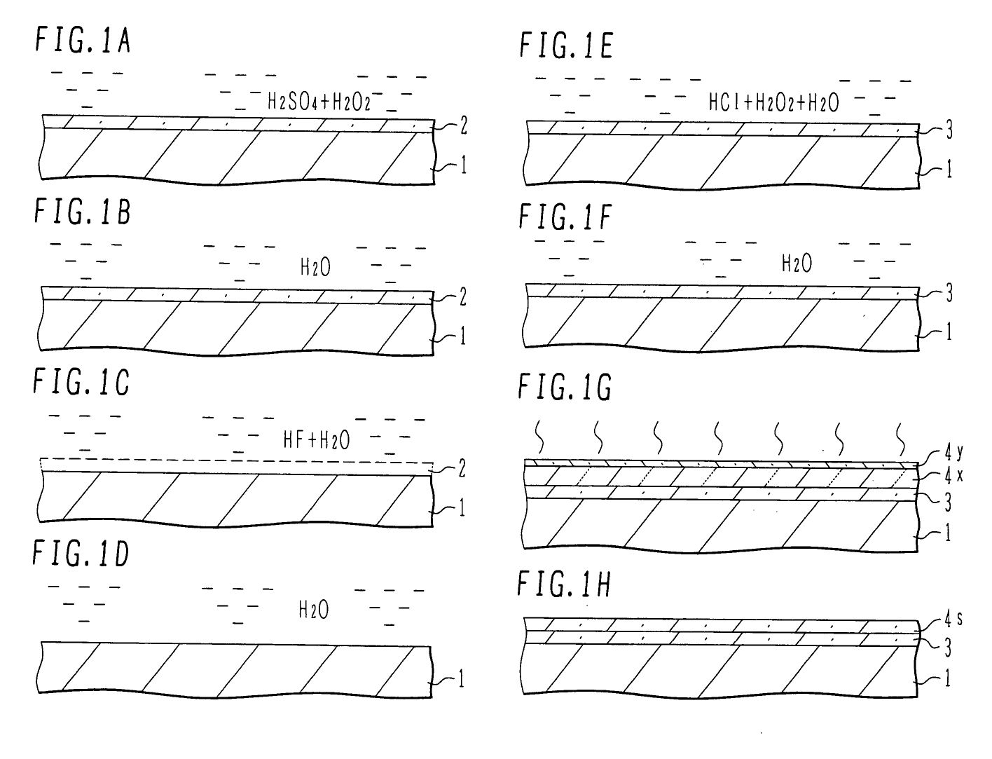

As shown in FIG. 1A, the surface of a silicon substrate 1 was washed with H₂SO₄+H₂O₂ (SPM). The silicon substrate 1 has on its surface a natural oxide film 2 because it was placed in the air. Organic contamination attached to the surface of the natural oxide film 2 is washed.

As shown in FIG. 1B, the silicon substrate was washed by flowing pure water for 10 minutes. Residues formed by washing with H₂SO₄+H₂O₂ are rinsed with pure water.

As shown in FIG. 1C, the silicon substrate 1 was immersed in dilute HF aqueous solution for about 1 minute to remove the natural oxide film 2 on the silicon substrate surface.

As shown in FIG. 1D, the silicon substrate was washed by flowing pure water for 10 minutes. Residues formed by the oxide film removing process by HF+H₂O are rinsed with pure water.

As shown in FIG. 1E, the silicon substrate was washed with SC2 (HCl+H₂O₂+H₂O) to form a chemical oxide film 3 of SC2 on the silicon surface to a thickness of about 0.3 nm. The silicon oxide 3 is purer and thinner than a natural oxide film. Since the silicon oxide film is formed on the silicon surface exposed and became water repellent, the surface becomes hydrophilic and generation of a water mark can be prevented.

As shown in FIG. 1F, the silicon substrate 1 was washed by flowing pure water for 10 minutes. Residues formed by the silicon oxide film forming process by SC2 are rinsed. Next, the substrate surface was dried by heat drying (in a nitrogen atmosphere). The processes up to this process are common for all samples. Thereafter, the silicon substrate was transported to a CVD film forming system. Prior to description of the process shown in FIG. 1G, description will be made on the CVD film forming system according to an embodiment.

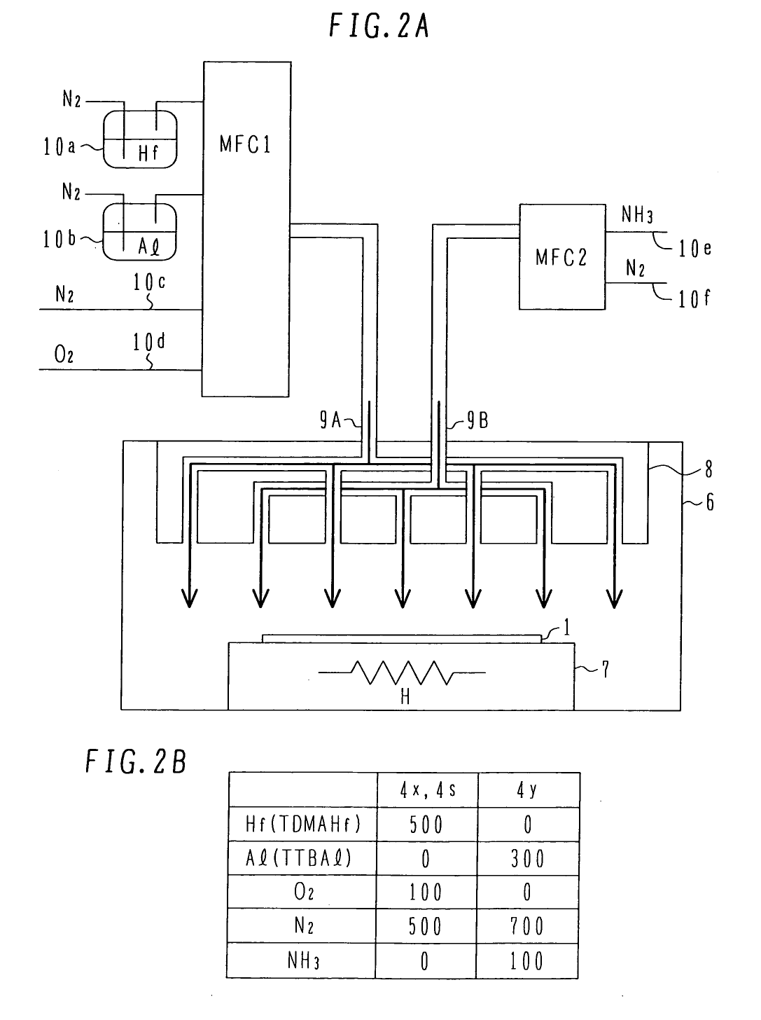

FIG. 2A it a schematic diagram showing the structure of a thermal CVD film forming system. A shower head 8 is disposed in a reaction chamber 6, and a suceptor 7 with a heater H is disposed under the shower head 8. Discrete pipes 9A and 9B are disposed in the shower head 8. The pipe 9A is coupled via a mass flow controller MFC1 to a hafnium source gas bubbler 10a, an aluminum source gas bubbler 10b, a nitrogen gas supply tube 10c and an oxygen gas supply pipe 10d.

The hafnium source gas bubbler 10a accommodates tetratertiarybutoxyhafnium (Hf(OtC₄H₉)₄, TTBHf) and uses nitrogen gas as bubbling gas. The aluminum source gas bubbler 10b accommodates tritertiarybutylaluminum (Al(t-C₄H₉)₃, TTBAl) and uses nitrogen gas as bubbling gas.

The mass flow controller MFC1 supplies organic source gasses of Hf and Al, nitrogen gas and oxygen gas at predetermined flow rates. These film forming gasses are supplied from the pipe 9A to the susceptor 7 via the shower head 8. The other pipe 9B disposed in the shower head 8 is connected via a mass flow controller MFC2 to an ammonia (NH₃) pipe 10e and a nitrogen pipe 10f. Aluminum is arranged to be supplied independently because if it is mixed with organic metal source gas, it may react with the organic metal source gas. The susceptor 7 is maintained at a constant temperature and a silicon wafer 1 placed thereon has the same temperature as that of the susceptor 7.

As shown in FIG. 1G, on the chemical oxide film 3 on the silicon substrate 1, a hafnium (HfO₂) film 4x having a thickness of 3 nm was formed and an aluminum nitride (AlN) film 4y having a thickness of 1 nm was formed on the hafnium film 4x, respectively by thermal CVD at a total flow rate of 1100 sccm, to form a sample S1 with a high dielectric constant insulating film of a lamination structure.

As shown in FIG. 1H, on the chemical oxide film 3, a single layer HfO₂ film 4s having a thickness of 4 nm was formed by thermal CVD at the total flow rate of 1100 sccm to form a comparative sample S3.

FIG. 2B is a table showing a flow rate of each film forming gas used when a high dielectric constant insulating layer of each sample was deposited. The source gasses used when the HfO₂ film 4x or 4s was formed on the silicon oxide film 3 are the nitrogen gas at 500 sccm containing (Hf(OtC₄H₉)₄ through bubbling, oxygen gas at 100 sccm and other nitrogen gas at 500 sccm. The total flow rate is 1100 sccm. Oxygen at 100 sccm is sufficient for forming a good quality oxide film preventing an oxygen-poor state.

The source gasses used when the AlN film 4y was formed on the HfO₂ film 4x are the nitrogen gas at 300 sccm containing (Al(t-C₄H₉)₃ through bubbling, NH₃ gas at 100 sccm and other nitrogen gas at 700 sccm. The total flow rate is 1100 sccm.

After the high dielectric constant insulating layer 4y or 4s was formed, post-deposition-annealing was performed for 30 seconds at 800° C. in a nitrogen atmosphere to make the deposited film dense and desorb C mixed by the organic material. Thereafter, a doped polysilicon layer was deposited by low pressure CVD (LPCVD) using silane as the source material to form samples of MOS diode structures. In place of the polysilicon layer, a lamination structure including a silicide layer, a metal layer containing Ti, W or Al, a polycide layer or the like may be used to select the structure having a low contact resistance of the gate electrode contacting a contact plug.

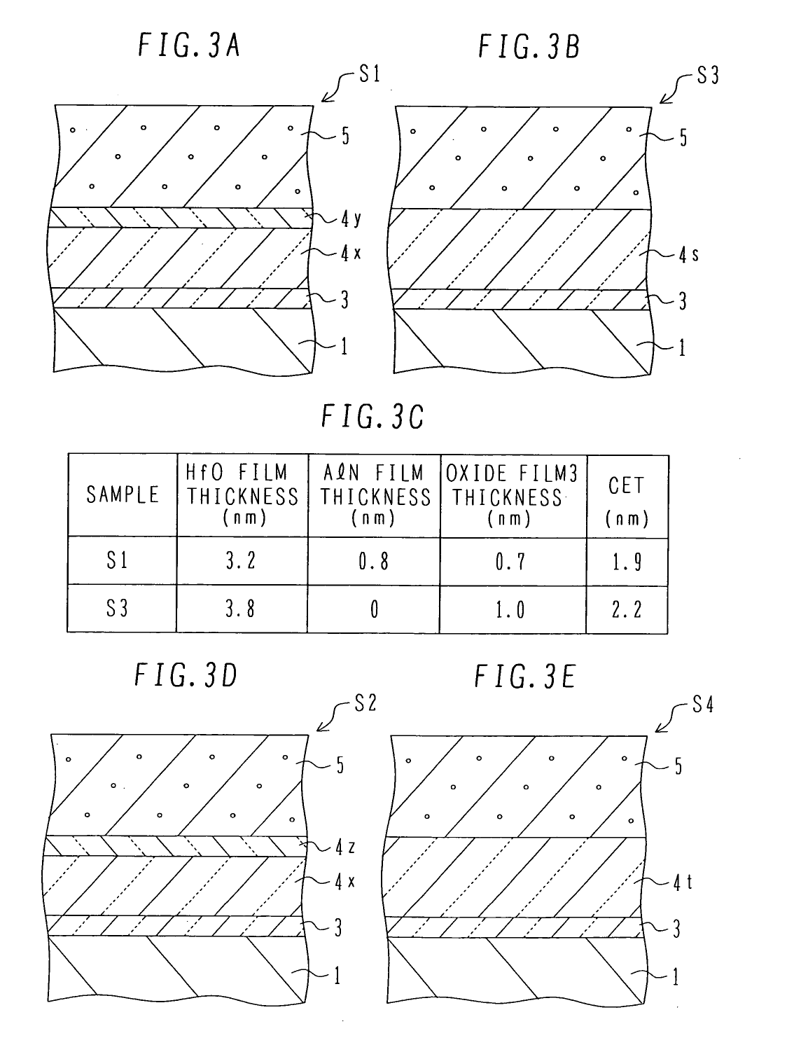

FIGS. 3A and 3B show the structures of two samples. FIG. 3A shows the structure of the sample S1 according to the embodiment. On the surface of the silicon substrate 1, the silicon oxide film 3 of chemical oxide is formed, a lamination layer of the HfO₂ layer 4x and AlN layer 4y is formed on the silicon oxide layer 3, and the silicon layer 5 is formed on the lamination layer. FIG. 3B shows the structure of the sample S3 according to the prior art. In place of the lamination layer of the high dielectric constant insulating layers 4x and 4y, the single layer HfO₂ layer 4s is formed.

FIG. 3C is a table showing each film thickness obtained from a sample cross section taken with a transmission electron microscope (TEM), and a capacitor equivalent film thickness CET (a film thickness converted to that of a silicon oxide film) obtained from the capacitance-voltage (C-V) measurement. In the sample S1 according to the embodiment, a thickness of the HfO₂ film 4x is 3.2 nm, a thickness of the AlN film 4y is 0.8 nm (a total thickness of the high dielectric constant insulating films 4x and 4y is 4 nm), a thickness of the underlying oxide film 3 is 0.7 nm, and CET is 1.9 nm. In the sample S3 according to the prior art, a thickness of the HfO₂ film 4s is 3.8 nm which is thinner than the total thickness 4.0 nm of the high dielectric constant insulating films of the sample S1, a thickness of the oxide film 3 is 1 nm which is thicker than the sample S1 by 0.3 nm, and CET is 2.2 nm which is thicker than the sample S1 by 0.3 nm.

The total thicknesses of the insulating films are 4.7 nm for the sample S1 and 4.8 nm for the sample S2, generally being equal. However, CET for the sample S1 is thinner than the sample S2 by 0.3 nm. It can be expected that the controllability of the gate voltage of the sample S1 is high because the oxide film 3 is maintained thin and CET is thin. It can also be expected that a change in CET can be suppressed even if the gate electrode 5 made of material capable of transmitting and supplying oxygen contacts the AIN layer 4y.

FIG. 3D is a diagram showing the structure of a sample S2 having an HfN film 4x in place of the AIN film 4y of the sample S1 shown in FIG. 3A. FIG. 3E is a diagram showing the structure of a sample S4 having a single HfN film 4t on the silicon oxide film in place of the HfO₂ film 4s of the sample S3 shown in FIG. 3B. A sample S5 was also formed which had a single layer Hf_{0.5}Al_{0.5}O_{y} film formed on the silicon oxide film.

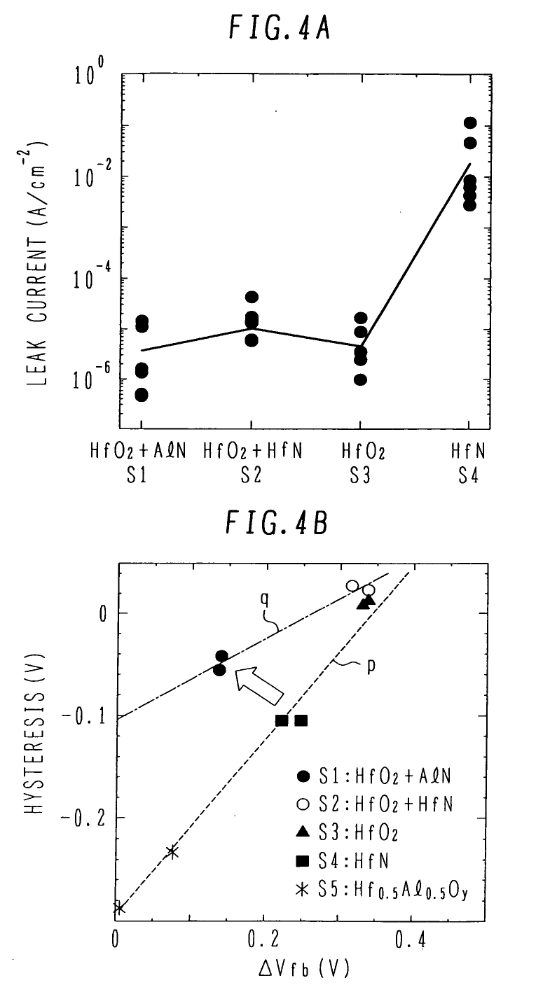

FIG. 4A is a graph showing measured leak currents of the samples S1 to S4. The measurement conditions are as follows.

A precision semiconductor parameter analyzer 4156C manufactured by Agilent Technologies was used for the measurements by sweeping the gate voltage of a MOS diode.

Only the sample S4, which has the single layer HfN film 4t as the high dielectric constant film formed on the silicon oxide film 3, shows a large leak current reaching 10⁻³ to 10⁻¹ A/cm². Some hafnium nitride films cannot be said insulative. The leak currents of the other samples are 10⁻⁴ A/cm⁻² or smaller. Among others, the sample S3 having the single HfO₂ layer as the high dielectric constant film and the sample S1 having the HfO₂/AlN lamination as the high dielectric constant film have a small leak current. From the other viewpoint, even if the single HfN layer cannot be used as a gate insulating film because of a large leak current, the HfO₂/HfN lamination layer can be used as a gate insulating film.

FIG. 4B is a graph showing the relation between a hysteresis obtained from the C-V measurements and a shift amount ΔVfb of a flat band voltage from the ideal value expected from material science, respectively measured for the samples S1 to S5. In this graph, the upper left region is a desired region where both the values are small, whereas the lower right region is an undesired region where both the values are large.

For the sample S3 having the single HfO₂ layer as the high dielectric constant film, although the hysteresis is as small as generally 0, ΔVfb is large at about 0.33 V. For the sample S4 having the single HfN layer as the high dielectric constant film, although the ΔVfb reduces to about 0.24 V, the hysteresis increases to about −0.1 V or larger. For the sample S5 having the single Hf_{0.5}Al_{0.5}O_{y} as the high dielectric constant film, although ΔVfb reduces lower than about 0.1 V, the hysteresis increases to a value larger than −0.2 V. The measurement values of the samples S3 to S5 having the single high dielectric constant films of these three types are almost on a straight line p, and it can be considered that the relation between the flat band voltage shift amount ΔVfb and hysteresis are in a trade-off relation.

For the sample S1 having the HfO₂/AlN lamination layer as the high dielectric constant film, ΔVfb is as small as about 0.15 V and the hysteresis is also small at about −0.05 V. The sample S1 moves from the straight line p very near to the origin (0, 0), and the characteristics thereof are improved considerably. Although the single HfO₂ film has large fixed charges, fixed charges are assumed to be reduced because the surface of the HfO₂ film is covered with the AlN film. It has been found that the hysteresis can be reduced and CET can be maintained low.

For the sample S2 having the HfO₂/HfN lamination layer as the high dielectric constant film, although the flat band voltage shift amount ΔVfb is as large as about 0.3 V, the hysteresis is about 0.05 V and the sample S2 is slightly on the origin (0, 0) side apart from the straight line p indicating the conventional characteristics. However, since HfN may have conductivity, if the conductivity is imparted, fixed charges will be reduced obviously.

Aluminum nitride and hafnium nitride are able to become mixture and insulator. If an aluminum-hafnium nitride (AlHfN) film is formed on a hafnium oxide film, the characteristics are expected on a straight line q. If hafnium oxide is covered with aluminum-hafnium nitride (Al₁₋ₓHfₓN, 0≦x≦1), it is expected to form a gate insulating film whose hysteresis and flat band voltage shift amount are improved.

Similar effects can be expected by adding silicon nitride to aluminum nitride. Even if nitride films are formed, some films contain oxygen if they are placed in the air. This oxygen containing film is also called a nitride film if it has the characteristics of the nitride film such as the above-described reaction suppression.

Hafnium nitride is the substance easy to be crystallized so that it is difficult to form a thin film having a uniform thickness. If a gate insulating film is formed on a silicon substrate by using only hafnium oxide, a crystalline insulating film having large leak current is likely to be formed. Crystallization can be suppressed if aluminum oxide (alumina) (AlO) or silicon oxide (SiO) is mixed to hafnium oxide (HfO₂). If aluminum oxide or silicon oxide is added to the hafnium oxide film of the above-described samples, it can be expected that the characteristics of the hysteresis—flat band voltage shift amount are improved.

As crystallization is suppressed, leak current is reduced. Aluminum oxide and silicon oxide have a dielectric constant lower than that of hafnium oxide. In order to obtain a dielectric constant as high as possible, it is preferable to limit the amount of aluminum oxide or silicon oxide to be mixed to hafnium oxide to (0<x<0.3) in the chemical formulas Hf₁₋ₓSi^{x}O and Hf₁₋ₓAlₓO. (0.1<x<0.3) is preferable from the viewpoint of crystallization suppression.

The cause of reaction when a hafnium oxide film is used as a gate insulating film may be mainly diffusion of oxygen. If oxide other than hafnium oxide is used as the high dielectric constant film, similar effects may be expected from the viewpoint of oxygen diffusion suppression. A high dielectric oxide layer may be an oxide layer or a lamination layer made of Hf, Ti, Ta, Zr, Y, W, or Al or a mixture thereof. The dielectric constant of the high dielectric constant film is preferably larger than 10. Nitrogen of a small amount may be added to the high dielectric constant oxide layer. This film is also called an oxide film.

In the above description, the silicon oxide layer of chemical oxide obtained by washing a silicon substrate with SC2 is used as the underlying layer of the high dielectric constant oxide layer. The surface of the silicon substrate may be nitridized. This is also called silicon oxide. Nitrogen may be introduced by another method. A thin silicon oxide layer may be formed by a method other than washing with SC2. Not only a wet process but also a dry process may be performed. A nitride layer may be inserted into a high dielectric constant oxide film. A silicon nitride film may be formed on the high dielectric constant oxide film to intercept oxygen supplied from the gate electrode. In this case, if the silicon nitride film is made thin, stress can be controlled. An embodiment using the silicon nitride film will be later described.

It is expected that an HfAlO film can be grown reliably by CVD at a substrate temperature of 400° C. to 600° C.

The source gas of Hf is not limited to (Hf(OtC₄H₉)₄). Hf[N(CH₃)₂]₄, Hf{N(C₂H₅)₂}₄, Hf{N(CH₃)(C₂H₅)}₄ and the like may be used. The source gas of Al is not limited to Al(t-C₄H₉)₃. Al(C₂H₅)₃, Al(CH₃)₃ and the like may be sued. Although the source gas is not limited to organic metal, the possibility of using organic metal source gas is high. In addition to NH₃ as nitridation gas, bistertiarybutylaminosilane (SiH₂[NHt-C₄H₉]₂, BTBAS), triethylamine (N(C₂H₅)₃, TEN) and the like may be used.

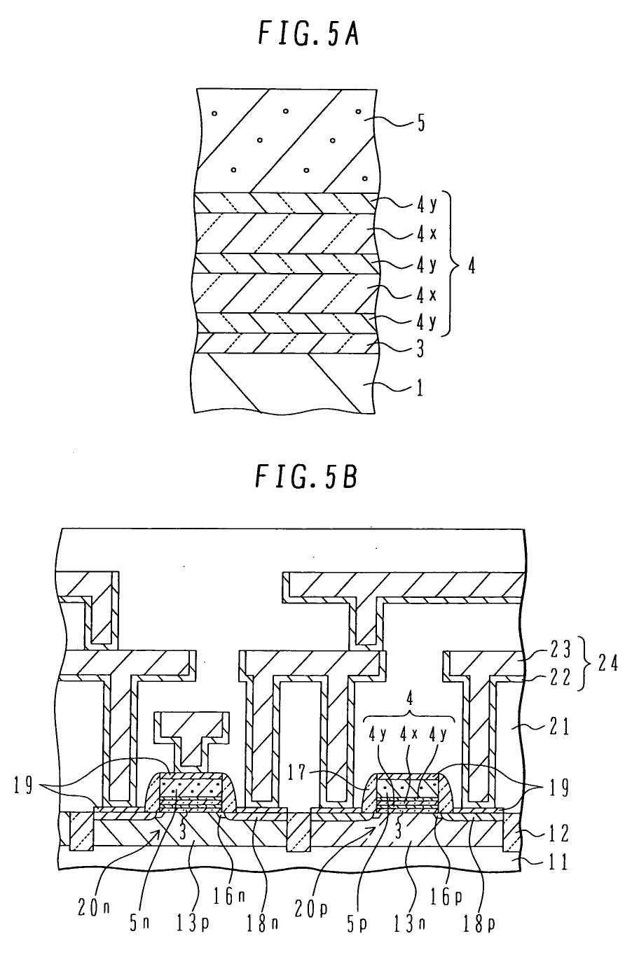

FIG. 5A shows the structure of a gate insulating film according to another embodiment. The structure that a silicon oxide layer 3 of chemical oxide is formed on the surface of a silicon substrate 1 is similar to that shown in FIG. 3A. In this embodiment, an aluminum nitride layer 4y and a hafnium oxide layer 4x are alternately stacked. In the structure shown in FIG. 5A, two hafnium oxide layers 4x are sandwiched by three aluminum nitride layers 4y. A silicon gate electrode 5 is formed on the uppermost aluminum nitride layer 4y. The number of stacked layers may be increased and decreased properly. A nitride layer is disposed at least at the position where the gate electrode 5 contacts the silicon oxide layer 3.

FIG. 5B shows an example of a semiconductor device of a CMOS structure. A silicon substrate 11 has an element isolation region 12 formed by shallow trench isolation (STI) and defining active regions. An n-type well 13n and a p-type well 13p are formed in the active region. An n-channel IG-FET 20n is formed in the p-type well 13p, and a p-channel IG-FET 20p is formed in the n-type well 13n. On the surface of the active region, a silicon oxide layer 3 of chemical oxide is formed, and on this silicon oxide layer 3, a high dielectric constant insulating lamination layer 4 is formed which has a hafnium oxide film 4x by CVD sandwiched by a pair of aluminum nitride films 4y. On the high dielectric constant insulating lamination layers 4, gate electrodes 5n and 5p of polysilicon are formed. The suffixes p and n after the reference numerals indicate the conductivity types. Side wall spacers 17 are formed on the side walls of the gate electrode. On both sides of the gate electrode, source/drain regions 18n and 18p with extensions 16n and 16p are formed. A silicide layer 19 is formed on the surfaces of the gate electrodes and source/drain regions. The p-channel IG-FET 20p has the structure that the conductivity type of each semiconductor region of the n-channel IG-FET 20n is reversed.

The high dielectric constant insulating film including the lamination of a hafnium oxide film and aluminum nitride films has CET of 2 nm or smaller, a small hysteresis, and a suppressed flat band voltage shift ΔVfb.

An interlayer insulating film 21 is formed covering the gate electrode, and a multi-layer wiring 24 is formed in the interlayer insulating film 21. Each wiring 24 is constituted of a barrier metal layer 22 and a main wiring layer 23 of copper or the like.

It has been found that as the aluminum nitride layer is disposed between an HfO₂ film as the high dielectric constant insulating film in the gate insulating film and the gate electrode of polysilicon, an increase in the thickness of the oxide film and reaction of the high dielectric constant film can be suppressed, the physical film thickness can be made thick and the capacitor equivalent film thickness can be made thin. It is known that silicon nitride has a high oxygen interception capability, and the silicon nitride is expected to present the effects similar to aluminum nitride. Although hafnium nitride may become conductive, hafnium oxynitride is able to become insulator and has the possibility that it becomes a good gate insulating film having a high dielectric constant.

Hafnium oxide is the substance easy to be crystallized. If a gate insulating film is formed on a silicon substrate by using only hafnium oxide, a crystalline insulating film having a large leak current is likely to be formed. Crystallization can be suppressed and leak current can be reduced if aluminum oxide (alumina) (Al₂O₃) is mixed to hafnium oxide (HfO₂). Aluminum oxide has a dielectric constant lower than that of hafnium oxide. Therefore, in order to suppress crystallization and obtain a dielectric constant as high as possible, the amount of aluminum oxide mixed to hafnium oxide is preferably Hf₁₋ₓAlₓO (0.1<x<0.3).

Thermal chemical vapor deposition (CVD) can form such a high dielectric constant insulating film having a good film quality, without adversely affecting the substrate. As an HfAlO film is formed by thermal CVD, the flat band voltage is shifted from a value (ideal value) expected from material science. A change in the flat band voltage may be ascribed to fixed charges. For example, if a silicon oxide layer having a limited thickness is formed on the surface of a silicon substrate and a high quality HfAlO film supplied with sufficient oxygen is formed on the silicon oxide layer, the underlying silicon oxide layer or a reaction layer grows unnecessarily. Fixed charges exist in this reaction layer and it can be considered that the fixed charges show the flat band voltage. It can be considered that as a gate electrode of polysilicon is formed on the HfAlO film, a silicon oxide layer or reaction layer is grown at the interface between the HfAlO film and polysilicon layer and fixed charges are generated.

As the oxygen supply during forming an HfAlO film is suppressed as small as possible, it is possible to suppress the formation of the reaction layer and the generation of fixed charges. In this case, it can be considered that the grown HfAlO film is in an oxygen-poor state and traps are formed and a hysteresis is generated in the relation between the capacitor (C)-voltage (V).

The present inventors have studied the structure having the advantages of the HfAlO films of the above-described two types and cancelling the disadvantages. In order to suppress hysteresis, a high dielectric constant oxide layer is deposited at a sufficient oxygen supply amount. In order to form a high dielectric constant insulating film having a small flat band voltage shift amount, it is desired to suppress diffusion of oxygen and the like to the interface between the high dielectric constant insulating layer and an adjacent layer. In order to suppress the diffusion, an HfAlO film having a low oxygen concentration is effective. An AlO film has a low oxygen diffusion coefficient and is expected to be more effective. HfAlO having a high Al concentration is expected to be more effective than HfAl having a low Al concentration. In the following, description will be made along with the experiments made by the present inventors.

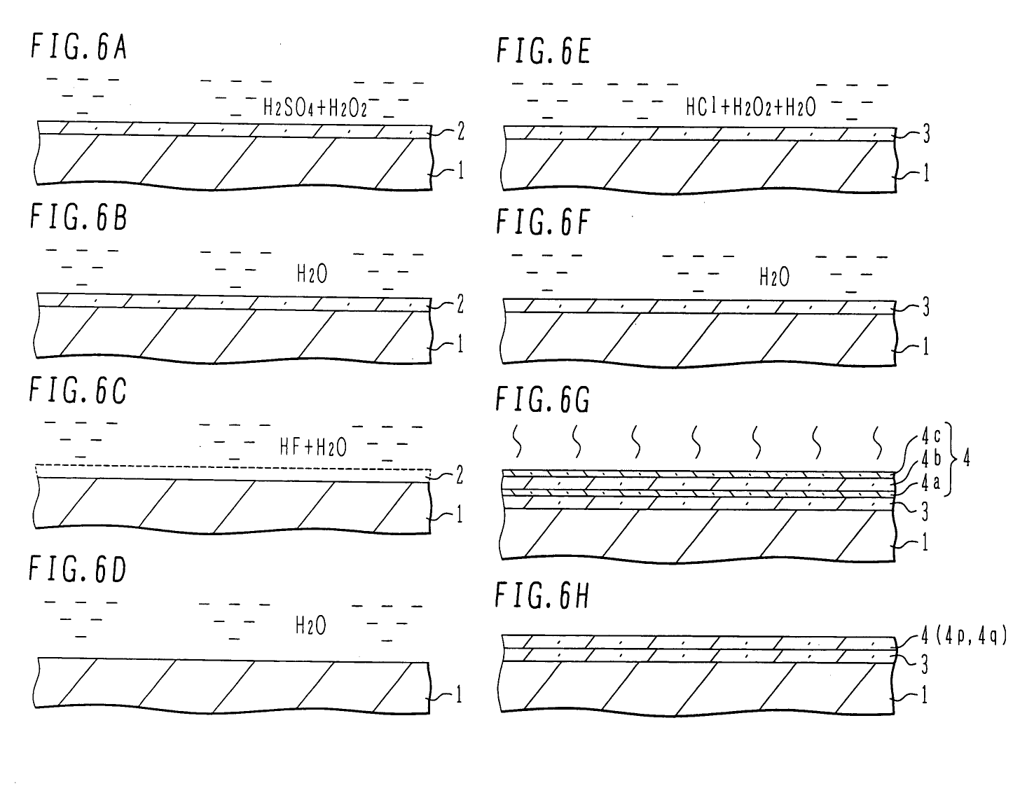

As shown in FIG. 6A, the surface of a silicon substrate 1 was washed with H₂SO₄+H₂O₂ (SPM). The silicon substrate 1 has on its surface a natural oxide film 2 because it was placed in the air. Organic contamination attached to the surface of the natural oxide film 2 is washed.

As shown in FIG. 6B, the silicon substrate was washed by flowing pure water for 10 minutes. Residues formed by washing with H₂SO₄+H₂O₂ are rinsed with pure water.

As shown in FIG. 6C, the silicon substrate 1 was immersed in dilute HF aqueous solution to remove the natural oxide film 2 on the silicon substrate surface.

As shown in FIG. 6D, the silicon substrate was washed by flowing pure water for 10 minutes. Residues formed by the oxide film removing process by HF+H₂O are rinsed with pure water.

As shown in FIG. 6E, the silicon substrate was washed with SC2 (HCl+H₂O₂+H₂O) to form a chemical oxide film 3 of SC2 on the silicon surface to a thickness of about 0.3 nm. The silicon oxide 3 is purer and thinner than a natural oxide film 2. Since the silicon oxide film is formed on the silicon surface exposed and became water repellent, the surface becomes hydrophilic and generation of a water mark can be prevented.

As shown in FIG. 6F, the silicon substrate 1 was washed by flowing pure water for 10 minutes. Residues formed by the silicon oxide film forming process by SC2 are rinsed. Next, the substrate surface was dried by heat drying (in a nitrogen atmosphere). The processes up to this process are similar to those shown in FIGS. 1A to 1F and common for all samples. Thereafter, the silicon substrate was transported to a CVD film forming system. Prior to description of the process shown in FIG. 6G, description will be made on the CVD film forming system according to an embodiment.

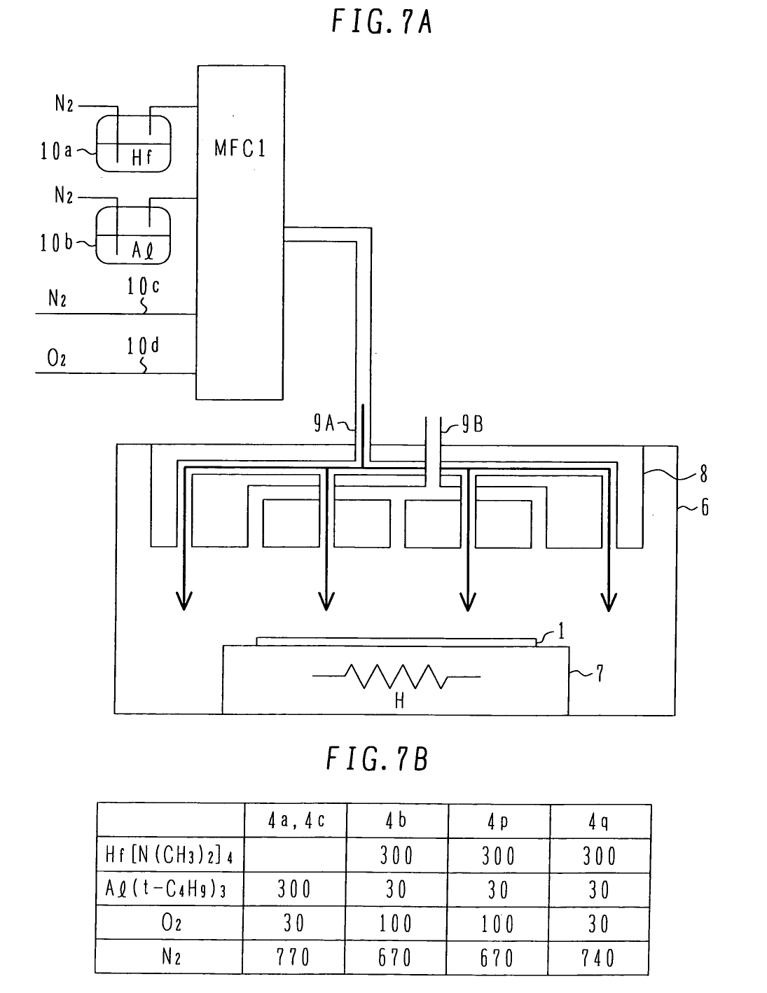

FIG. 7A is a schematic diagram showing the structure of a thermal CVD film forming system. A shower head 8 is disposed in a reaction chamber 6, and a suceptor 7 with a heater H is disposed under the shower head 8. Discrete pipes 9A and 9B are disposed in the shower head 8. The pipe 9A is coupled via a mass flow controller MFC1 to a hafnium source gas bubbler 10a, an aluminum source gas bubbler 10b, a nitrogen gas supply tube 10c and an oxygen gas supply pipe 10d. Although this system is similar to the structure of the CVD film forming system shown in FIG. 2A, the pipe 9B is not used.

The hafnium source gas bubbler 10a accommodates tetrakisdimethylaminohafnium (Hf[N(CH₃)₂]₄) and uses nitrogen gas as bubbling gas. The aluminum source gas bubbler 10b accommodates tritertiarybutylaluminum (Al(t-C₄H₉)₃) and uses nitrogen gas as bubbling gas.

The mass flow controller MFC1 supplies source gasses of Hf and Al, nitrogen gas and oxygen gas at predetermined flow rates. These film forming gasses are supplied from the pipe 9A to the susceptor 7 via the shower head 8. The other pipe 9B is disposed also in the shower head 8 and can supply other gasses independently from the pipe 9A. The susceptor 7 is maintained at a temperature of 500° C. and the temperature of a silicon wafer 1 placed thereon is also 500° C.

As shown in FIG. 6G, on the chemical oxide film 3 on the silicon substrate 1, an AlO film 4a having a thickness of 0.5 nm, an HfAlO film 4b having a thickness of 2.5 nm and an AlO film 4c having a thickness of 0.5 nm were formed in this order by thermal CVD at a total flow rate of 1100 sccm, an atmosphere pressure of 65 Pa and a substrate temperature of 500° C., to form a high dielectric constant insulating film 4 of a lamination structure. Prior to describing a comparative sample shown in FIG. 6H, description will be made on film forming gasses used for forming each sample according to an embodiment.

FIG. 7B is a table showing a flow rate of each film forming gas used when a high dielectric constant insulating layer of each sample was deposited. The source gasses used when the AlO film 4a was formed on the silicon oxide film 3 are the nitrogen gas at 300 sccm containing (Al(t-C₄H₉)₃ through bubbling, oxygen gas at 30 sccm and other nitrogen gas at 770 sccm. The total flow rate is 1100 sccm. Oxygen gas at 30 sccm is the minimum flow rate for growing an oxide layer. The AlO₄ film 4a is grown in a very oxygen-poor state.

The source gasses used when the HfAlO film 4b was formed on the AlO film 4a are the nitrogen gas at 300 sccm containing (Hf[N(CH₃)₂]₄) through bubbling, nitrogen gas at 30 sccm containing (Al(t-C₄H₉)₃ through bubbling, oxygen gas at 100 sccm and other nitrogen gas at 670 sccm. The total flow rate is 1100 sccm. The composition of HfAlO was Hf_{0.8}Al_{0.2}O. The oxygen gas at 100 sccm is sufficient for preventing the oxygen-poor state and providing a sufficient oxygen concentration.

The source gasses used when the AlO film 4c was formed on the HfAlO film 4b are, similar to the AlO film 4a, the nitrogen gas at 300 sccm containing (Al(t-C₄H₉)₃ through bubbling, oxygen gas at 30 sccm and other nitrogen gas at 770 sccm. The total flow rate is 1100 sccm.

Referring again to FIG. 6G, the high dielectric constant insulating lamination layer 4 is constituted of the HfAlO film 4b formed by supplying sufficient oxygen sandwiched by the AlO films 4a and 4C formed by considerably reducing the oxygen supply amount. The chemical oxide film 3 and high dielectric constant insulating lamination layer 4 constitute a composite insulating film. A doped silicon film is formed on the composite insulating film to form an insulated gate electrode.

As shown in FIG. 6H, a comparative sample was formed by forming a single HfAlO film 4 on the chemical oxide film 3 by thermal CVD at a substrate temperature of 500° C., an atmosphere pressure of 65 Pa and a total flow rate of 1100 sccm. An HfAlO film 4p was formed by supplying a sufficient oxygen amount and an HfAlO film 4q was formed by limiting the oxygen supply amount as small as possible.

The source gasses used when the HfAlO film 4p was formed are, similar to the HfAlO film 4b, the nitrogen gas at 300 sccm containing (Hf[N(CH₃)₂]₄) through bubbling, nitrogen gas at 30 sccm containing (Al(t-C₄H₉)₃ through bubbling, oxygen gas at 100 sccm and other nitrogen gas at 670 sccm. The HfAlO film 4p was formed to a total thickness of 3.5 nm under the oxygen-rich condition.

The source gasses used when the HfAlO film 4q was formed are the nitrogen gas at 300 sccm containing (Hf[N(CH₃)₂]₄) through bubbling, nitrogen gas at 30 sccm containing (Al(t-C₄H₉)₃ through bubbling, oxygen gas at 30 sccm and other nitrogen gas at 740 sccm. The HfAlO film 4q was formed to a total thickness of 3.5 nm under the condition that the oxygen supply amount is reduced greatly.

After the high dielectric constant insulating layer 4 was formed, post-deposition-annealing was performed for 30 seconds at 800° C. in a nitrogen atmosphere. Thereafter, a doped polysilicon layer was deposited by low pressure CVD (LPCVD) using silane as the source material to form the MOS diode structure. In place of the polysilicon layer, a metal gate structure including a silicide layer or Ti, W or Al may be used to select the material structure having a low contact resistance of the gate electrode contacting a contact plug.

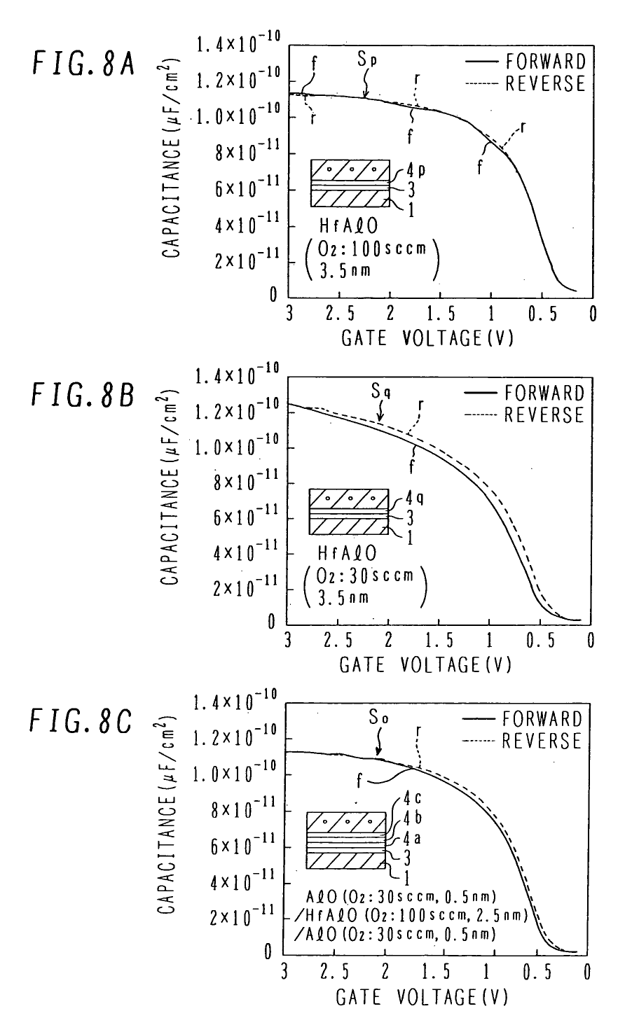

FIGS. 8A, 8B and 8C show the CV measurement results of MOS diode structures formed by using three types of samples. FIG. 8A shows the CV measurement of a sample Sx whose HfAlO film 4p was grown under a sufficient oxygen supply (100 sccm). The hysteresis is as very small as about −3.5 mV. The flat band voltage shift amount is as large as about 0.65 V. FIG. 8B shows the CV measurement of a sample 4y whose HfAlO film 4y was grown by considerably reducing the oxygen supply amount (30 sccm). The hysteresis is as very large as about −56 mV. The flat band voltage shift amount is lowered to about 0.57 V. FIG. 8C shows the CV measurement of a sample So of the high dielectric constant lamination layer 4. The hysteresis is about −26 mV in an allowable range. The flat band voltage shift amount is as small as about 0.57 V.

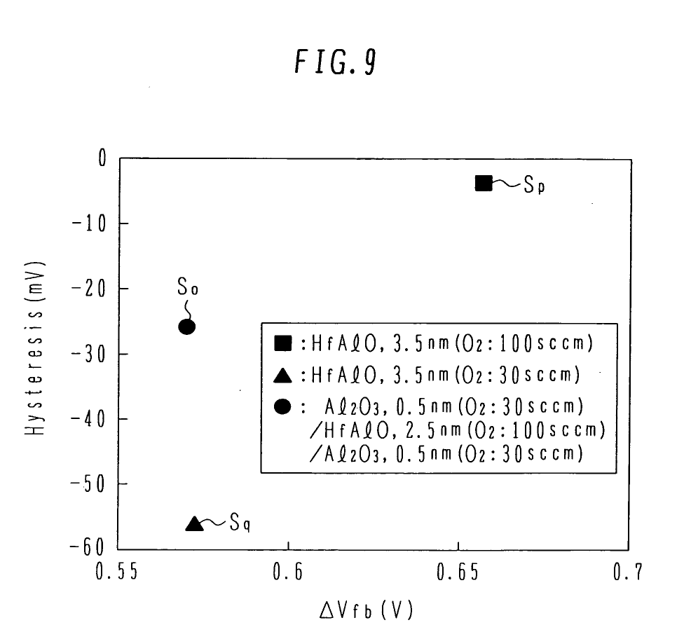

These measurement results are summarized in FIG. 9. The abscissa represents a flat band voltage shift amount ΔVfb in the unit of V and the ordinate represents a hysteresis in the unit of mV. The upper left region is the region having the excellent characteristics. It is clearly shown that the characteristics of the sample So are excellent as compared to the comparative samples Sp and Sq.

Since the comparative sample Sp is formed by supplying sufficient oxygen, the oxygen-poor state does not exist in the film. However, it can be considered that oxygen is supplied to the interface between the underlying silicon oxide film 3 and polysilicon gate electrode so that the reaction layer is formed and fixed charges are generated.

Since the comparative sample Sq is formed by considerably reducing the oxygen supply amount, the oxygen supply amount to the interface between the underlying silicon oxide film and polysilicon gate electrode is supposed to suppress the formation of a reaction layer and the generation of fixed charges so that the flat band voltage shift amount is small. However, it can be considered that since the oxygen supply amount is very small, the oxygen-poor state occurs and traps are increased.

Referring again to FIG. 6G, for the lamination layer sample So, the surface layers of the high dielectric constant insulating layer 4 are made of the AlO films 4a and 4c having an oxygen diffusion coefficient smaller than that of HfAlO. It is possible to suppress the diffusion of oxygen from the HfAlO film 4b sandwiched between the AlO films 4a and 4c having a small oxygen diffusion coefficient, to an external. When the AlO films 4a and 4c are formed, an oxygen supply amount is lowered. Similar to the comparative sample Sq, the oxygen supply amount is small. It can therefore be considered that diffusion of oxygen to the interface between the underlying silicon oxide layer and polysilicon layer can be suppressed. It can be considered that since the AlO film 4a is formed first and thereafter the AlO film 4c is formed, even if sufficient oxygen is supplied when the HfAlO film 4b is formed, the supplied oxygen is suppressed from being supplied to the interface between the underlying silicon oxide layer and the polysilicon layer to be formed thereafter. It is expected that the formation of a reaction layer and a shift of the flat band voltage are suppressed. It can be considered that since the HfAlO film 4b, the main portion of the high dielectric constant insulating film, is formed by supplying sufficient oxygen, the number of traps reduces and the hysteresis is suppressed. The gate electrode material which may be oxidized depending upon the gate electrode forming conditions, such as a polysilicon layer, can be used. Therefore, the degree of freedom of the semiconductor device structure design can be improved. The oxygen diffusion coefficient does not depend upon the degree of an oxygen concentration.

The high dielectric constant oxide insulating film is divided into the central portion and opposite surface portions. The central portion is made of a film having a good quality and few traps and formed by supplying sufficient oxygen. The surface portions are made of films which are made to have a small oxygen diffusion coefficient by selecting the composition and to suppress the formation of a reaction layer and the generation of fixed charges by lowering the oxygen supply amount during the film formation. It can therefore be considered that a high dielectric constant oxide insulating film can be formed which has a small flat band voltage shift amount and a small hysteresis.

In the above description, as the underlying layer of the high dielectric oxide insulating film, the silicon oxide layer of chemical oxide is formed on a silicon substrate. The silicon substrate surface may be nitridized. Nitrogen may be introduced by another method. The method of forming a thin silicon oxide film is not limited to washing with SC2.

HfAlO is used as the material of the central portion of the high dielectric insulating film changing its characteristics in the thickness direction. Al in HfAlO is an additive agent for suppressing crystallization. HfO has the nature easy to be crystallized. In addition to Al, Si or the like may be used for crystallization suppression. If the crystallization suppressing conditions such as a thin film are satisfied, HfO may be used as the material of the central portion of the high dielectric constant insulating film. As the material of the central portion, not only HfO, but also other high dielectric constant oxide materials may be used, such as TiO, TaO, ZrO, YO, WO, AlO and LaO.

Although AlO is used as the material of the opposite surface portions of the high dielectric insulating film changing its characteristics in the thickness direction, it is not limited only to AlO. Although oxide having a small oxygen diffusion coefficient is typically AlO, AlO added with another element or a mixture of AlO and other insulator may also be used. For example, AlON obtained by adding N to AlO, HfAlO having a higher Al composition than that of the central portion HfAlO, or the like may also be used. Since AlO has a dielectric constant lower than that of HfO, HfO, TiO, TaO, ZrO, YO or WO may be added to raise the dielectric constant. Even if the compositions of Hf and Al are the same as the central portion HfAlO, HfAlO having a lower oxygen concentration may be used. It can be assumed from the measurement result of the sample 4q that the HfAlO film having a lower oxygen concentration has a small oxygen diffusion coefficient. Even if the composition is adjusted, it is preferable to suppress the oxygen supply amount. For example, in CVD for the high dielectric constant oxide lamination layer, the total flow rate is made constant, and the oxygen supply amount at the growth start and end stages is set to a half of or smaller than the oxygen supply amount at the growth middle stage.

The thickness of the opposite surface portions 4a and 4c having the oxygen diffusion suppressing effects is preferably set to 0.3 nm to 1 nm. If the thickness is thinner than 0.3 nm, it is difficult to obtain a sufficient oxygen diffusion suppressing effect. If the thickness is thicker than 1 nm, the silicon oxide equivalent film thickness becomes too thick. The thickness of the high dielectric constant layer 4b having a high dielectric constant is preferably 1 nm to 5 nm, and about 1 nm to 3 nm for a fine transistor. The total thickness of the opposite surface portions 4a and 4c is preferably thinner than the thickness of the central high dielectric constant insulating layer 4b.

The compositions of the central portion and opposite surface portions may be changed continuously or gradually instead of a stepwise change. In this case, the oxygen diffusion coefficient is expected to be changed continuously or gradually.

Although CVD film formation is performed at the substrate temperature of 500° C., the film forming temperature is not limited to 500° C. It is expected that an HfAlO film can be grown reliably at the film forming temperature of 400° C. to 600° C.

The Hf source gas is not limited to (Hf[N(CH₃)₂]₄). Hf(OtC₄H₉)₄, Hf{N(C₂H₅)₂}₄, Hf{N(CH₃)(C₂H₅)}₄ or the like may be used. The Al source gas is not limited to Al(t-C₄H₉)₃, but Al(C₂H₅)₃, Al(CH₃)₃ or the like may be used.

In the above description, HfAlO is formed by thermal CVD. Even if another high dielectric constant insulating film is grown by thermal CVD, the high dielectric constant insulating layer having a low oxygen diffusion coefficient is formed at the growth start and end stages. It can be considered that the hysteresis can be suppressed and the flat band voltage shift can be suppressed. Although the source gas is not limited to organic metal, the possibility of using organic metal source gas is high.

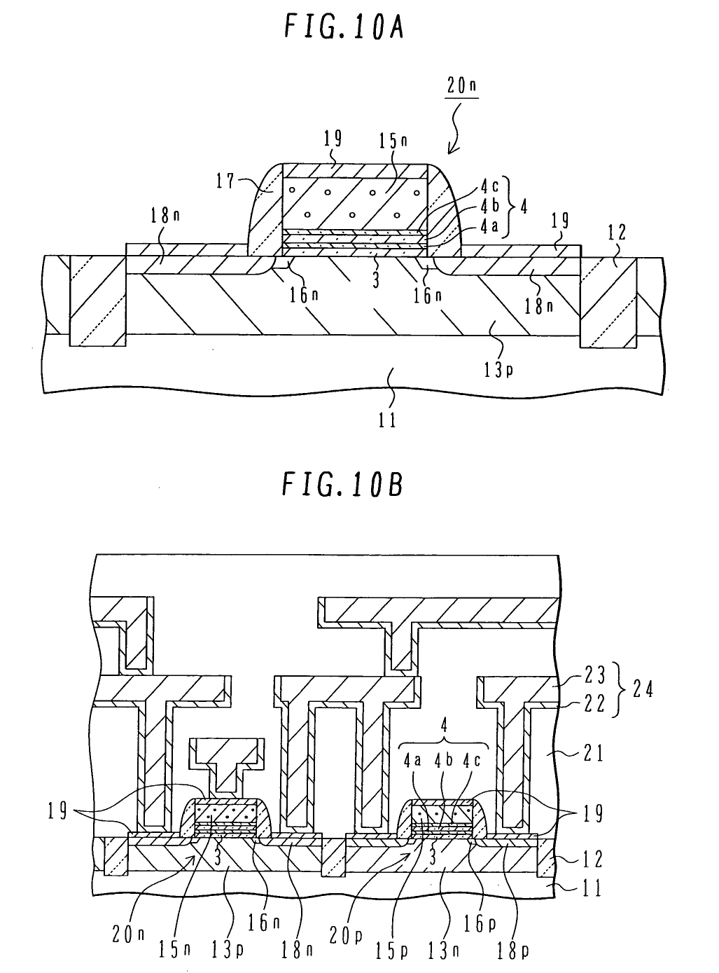

FIG. 10A shows the structure of an n-channel IG-FET. A silicon substrate 11 has an element isolation region 12 formed by shallow trench isolation (STI) and defining active regions. A p-type well 13p is formed in the active region. An n-type well is also formed in the active region at a different position. The above-described high dielectric constant gate insulating lamination film 4 is formed on a silicon oxide layer 3 on the active region surface. The gate insulating film 4 has the lamination structure that the high dielectric constant oxide insulating film 4b grown by supplying sufficient oxygen is sandwiched between the high dielectric constant oxide insulating films 4a and 4c having a low oxygen diffusion coefficient and formed under the condition that the oxygen supply amount is lowered.

An n-type polysilicon gate electrode 15n doped with phosphorus (P) or arsenic (As) is formed on the gate insulating film 4. In the surface layer on both sides of the gate electrode, n-type extension regions 16n are formed. Side wall spacers 17 of silicon oxide or the like are formed on the side walls of the gate electrode. In the substrate outside of the side wall spacers 17, high concentration n-type source/drain regions 18n are formed. A silicide layer 19 of CoSi or the like is formed on the surfaces of the gate electrode 15n and source/drain regions 18n. In this manner, an n-channel IG-FET 20n is formed.

With this structure, since the gate insulating film is made of the high dielectric constant insulating film, the physical film thickness can be made thick and the tunneling current can be suppressed, even if the equivalent silicon oxide film thickness is made thin. The structure of the stacked gate insulating film can suppress the hysteresis and the flat band voltage shift. Instead of silicon, the gate electrode may be made of aluminum. An aluminum electrode can be formed by aluminum sputtering or by replacing silicon with aluminum (substituting aluminum for silicon).

FIG. 10B shows an example of the structure of a semiconductor integrated circuit device. In a silicon substrate 11, an n-type well 13n and a p-type well 13p are formed. In the p-type well, the above-described n-channel IG-FET 20n is formed. In the n-type well, a p-channel IG-FET 20p is formed. The suffixes p and n after the reference numerals indicate the conductivity types. The p-channel IG-FET 20p has the structure that the conductivity type each semiconductor region of the n-channel IG-FET 20n is reversed.

The gate insulating film of both the n- and p-channel IG-FETs is made of a lamination layer formed on a silicon oxide film 3 whose thickness is limited. This lamination layer has the structure that an Hf_{0.8}Al_{0.2}O high dielectric constant insulating film 4b is sandwiched between the AlO films 4a and 4c having a low oxygen concentration. The high dielectric constant film has a small hysteresis and a suppressed flat band voltage shift ΔVfb. An interlayer insulating film 21 is formed covering the gate electrode, and a multi-layer wiring 24 is formed in the interlayer insulating film 21. Each wiring 24 is constituted of a barrier metal layer 22 and a main wiring layer 23 of copper or the like.

By involving the film having an oxygen intercepting capability at least between the HfO film and silicon layer, it is expected that the hysteresis can be reduced and the flat band voltage shift can be suppressed. The present inventors have studied further the results obtained when an HfO film is formed by stacking films made of various materials.

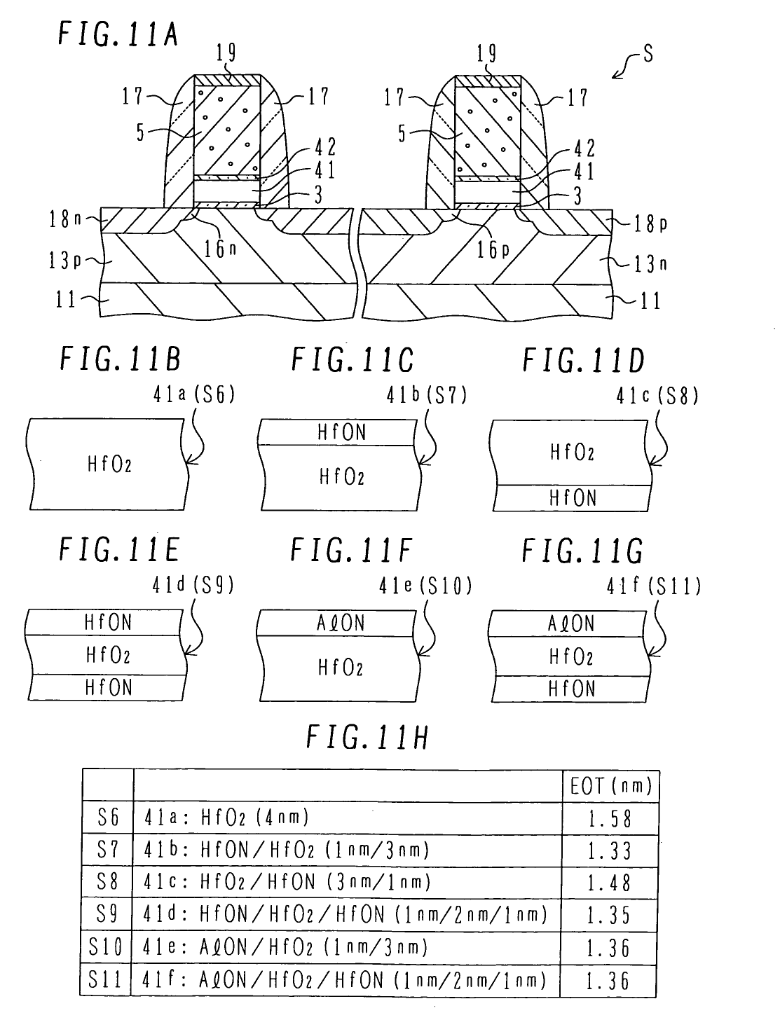

FIG. 11A is a schematic cross sectional view showing the structure of a manufactured sample S. An element isolation region for defining active regions was formed in a silicon substrate 11 and a p-type well 13p and an n-type well 13n were formed in an active region by implanting p-type impurity ions and n-type impurity ions. A silicon oxide film 3 was formed on the active region surface to a thickness of about 0.7 nm and a high dielectric constant insulating layer 41 having six types of structures was formed on the silicon oxide film 3 by metal organic chemical vapor deposition (MOCVD).

After the high dielectric constant insulating layer 41 is deposited, a heat process (annealing) was performed for 30 seconds in an N₂ atmosphere and at a temperature of 600° C. to 1100° C., e.g., at 800° C. to make the high dielectric constant layer dense and desorb C mixed by the organic material. Thereafter, a thin silicon nitride film 42 having a thickness thinner than 1 nm at the most was deposited, the silicon nitride film having the oxygen intercepting function and being used as a dielectric film having a dielectric constant higher than silicon oxide.

A polysilicon film 5 was deposited on the silicon nitride film 42, and an insulated gate electrode was formed by patterning using a resist pattern. An n-type extension region 16n and a p-type extension region 16p were formed by implanting n-type impurity ions in the p-type well 13p and p-type impurity ions in the n-type well 13n. A silicon oxide layer was deposited and anisotropically etched to form side wall spacers 17 on the gate electrode side walls. N-type source/drain regions 18n and p-type source/drain regions 18p were formed by implanting n-type impurity ions in the p-type well 13p and p-type impurity ions in the n-type well 13n.

FIGS. 11B to 11G show the design structures of six types of the high dielectric constant insulating layers 41. FIG. 11B shows a sample S6 for forming a high dielectric constant insulating layer 41a by using a single HfO₂ film having a thickness of 4 nm. FIG. 11C shows a sample S7 for forming a high dielectric constant insulating layer 41b by stacking an HfON film having a thickness of 1 nm on an HfO₂ film having a thickness of 3 nm. FIG. 11D shows a sample S8 for forming a high dielectric constant insulating layer 41c by stacking an HfO₂ film having a thickness of 3 nm on an HfON film having a thickness of 1 nm, reversing the upper and lower films of FIG. 11C. FIG. 11E shows a sample S9 for forming a high dielectric constant insulating layer 41d by sandwiching an HfO₂ film having a thickness of 2 nm between HfON films having a thickness of 1 nm. FIGS. 11F and 11G show samples S10 and S11 for forming high dielectric constant insulating layers 41e and 41f by replacing the upper HfON film shown in FIGS. 11C and 11E with an AlON film.

After six types of the samples S(S6 to S11) of CMOS structures are formed, an equivalent oxide film thickness (EOT, incorporating the effects by components other than capacitors) of the gate insulating film was measured. For the samples S6, S7 and S9, the drain current Id—gate voltage Vg characteristics were measured before and after the heat process. An apparatus 4156C manufactured by Agilent Technologies was used for the measurements of the current—voltage characteristics and an apparatus 4284A manufactured by Agilent Technologies was used for the measurements of the capacitance—voltage characteristics.

FIG. 11H is a table summarizing the measured EOTs. The sample S6 having the single HfO₂ film covered with the SiN film has EOT of 1.58 nm which suggests that a thin SiN film presents the oxygen intercepting capability. The sample S8 having the HfON film stacked on the HfO₂ film has EOT of 1.33 nm which is apparently reduced as compared to the sample S6 having EOT of 1.58 nm. It can be considered that the HfON film presents the oxygen intercepting capability, intercepts oxygen diffused from the polysilicon layer 5 and not intercepted by the thin SiN film and prevents the reaction. The sample S8 having the HfON film under the HfO₂ film has EOT of 1.48 nm which is thinner than the EOT of the sample S6. It can be considered that oxygen diffuses also from the lower silicon oxide film 3 and the lower HfON film intercepts this oxygen. The sample S9 having the HfON films sandwiching the HfO₂ film has EOT of 1.35 nm which is thinner than EOT of the sample S8 and supports the above-described consideration. However, the dielectric constant of HfON is larger than that of HfO₂, and if the ratio of the HfON film is set large, EOT may become large relatively.

The samples S10 and S11 replacing the HfON film with the AION film have EOTs of 1.36 nm and 1.36 nm, which values are near to EOTs of 1.33 nm and 1.35 nm of the samples S7 and S9.

It can be considered that the AlON film has also the oxygen intercepting capability similar to the HfON film. The nitride insulating films such as an AlN film, an SiN film, an HFON film and an AlOn film are considered having an effective oxygen intercepting capability. The SiN film may be omitted by forming an HfON film or an AlON film on the HfO₂ film. In the structure shown in FIG. 5A, the hafnium oxide layer 4x may be sandwiched between hafnium oxynitride layers or aluminum oxynitride layers 4y. The number of hafnium oxide layers may be increased or decreased.

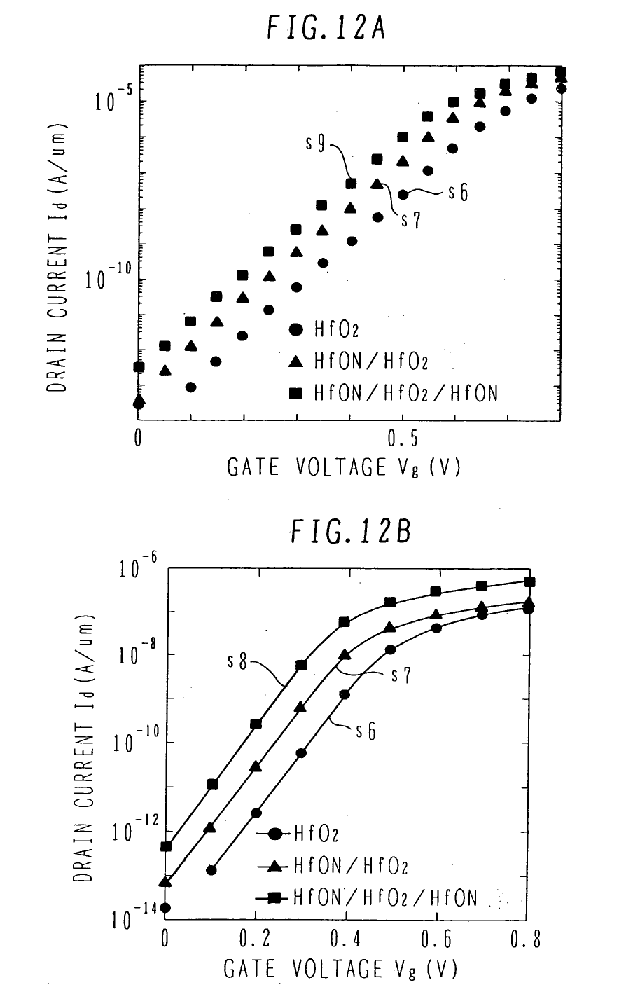

FIG. 12A shows the measurement results of the drain current Id-gate voltage Vg characteristics after the heat process of the samples S6, S7 and S9. In the characteristics s7 of the sample S7, the gate voltage shifts to the negative direction as compared to the characteristics s6 of the sample S6. The characteristics s9 of the sample S9 further shift to the negative direction. Assuming that negative fixed charges exist in the sample S6, the fixed charges of the samples S7 and S9 reduce. It can be considered that the fixed charges can be reduced by disposing the HfON film next to the HfO₂ film.

This phenomenon can be understood in the following manner. A deposited HfO₂ film has traps such as lattice defects which trap electrons. If N diffuses from the HfOn film into the HfO₂ film in the heat process, N functions to remove traps such as lattice defects. As traps disappear, electrons in the form of fixed charges can be extinguished. In the above-described heat process, N diffusing from one side will not be distributed over the whole thickness of the HfO₂ film. If the HfON film is disposed on both sides, this effect becomes larger than if the HfON film is disposed on one side.

FIG. 12B shows the simulation results based upon the above-described consideration. As the characteristics of the samples S6, S7 and S9, characteristics s6, s7 and s9 were obtained indicating similar tendencies to those shown in FIG. 12A. It can be considered that adequacy of the above-described consideration is supported.

In the structure that a nitride layer having the oxygen intercepting capability is disposed on the surface of a high dielectric constant oxide layer, it is preferable that the oxygen intercepting nitride film contains at least one of an AlN film and an SiN film. It can be considered that the HfON film and AINO film can be used both as the high dielectric constant oxide layer and as the oxygen intercepting nitride layer.

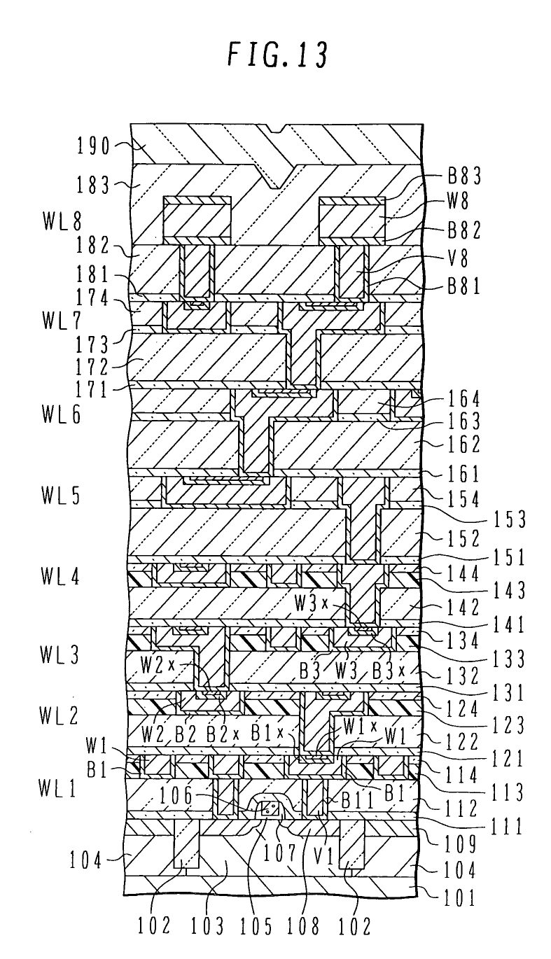

FIG. 13 shows an example of the structure of a semiconductor integrated circuit device having a multi-layer wiring structure. In a silicon substrate 101, an element isolation region 102 is formed by shallow trench isolation (STI). In the active region surrounded by the element isolation region 102, a p-type well 103 and an n-type well 104 are formed to form MOS transistors.

On the p-type well 103, a high dielectric constant gate insulating film 105 having the above-described structure 105, a polysilicon gate electrode 106 and side wall spacers 107 are formed, and on both sides of the gate electrode 106, n-type source/drain regions 108 with extensions are formed. In the n-type well 104, p-type source/drain regions 109 are formed.

A silicon nitride layer 111 is formed on the semiconductor substrate, covering the gate electrode. A phosphosilicate glass (PSF, phosphorus doped silicon oxide) layer 112 is formed on the silicon nitride layer 111. A via conductor constituted of a TiN barrier layer B11 and a tungsten layer V1 is formed through the PSG layer 112 and silicon nitride layer 111.

An organic insulating layer 113 and a silicon oxide layer 114 are stacked on the PSG layer 112. In this lamination layer, a wiring pattern is buried which is constituted of a barrier metal layer B1, a copper wiring layer W1, an auxiliary barrier metal layer B1x and an auxiliary copper wiring layer W1x. In this manner, a first wiring layer WL1 is formed.

On the first wiring layer WL1, a silicon nitride layer 121, a silicon oxide layer 122, an organic insulating layer 123, a silicon nitride layer 124 are stacked to form an interlayer insulating film for a second wiring layer WL2. In the second wiring interlayer insulating film, a second wiring layer WL2 is buried which is constituted of a barrier metal layer B2, a copper wiring layer W2, an auxiliary barrier metal layer B2x and an auxiliary copper wiring layer W2x.

Similar to the interlayer insulating film for the second wiring layer WL2, the interlayer insulating films for third and fourth wiring layers WL3 and WL4 are made of lamination layers constituted of silicon nitride layers 131 and 141, silicon oxide layers 132 and 142, organic insulating layers 133 and 143 and silicon oxide layers 134 and 144.

The structures of damascene wiring of the third wiring layer WL3 and fourth wiring layer WL4 are similar to that of the second wiring layer WL2. The wiring pattern is constituted of a barrier metal layer Bn, a copper wiring layer Wn, an auxiliary barrier metal layer Bnx and an auxiliary copper wiring layer Wnx.

A fifth wiring layer WL5 to a seventh wiring layer WL7 have the structure different from that of the second wiring layer WL2 to fourth wiring layer WL4. An interlayer insulating film of the fifth wiring layer WL5 is a lamination layer constituted of a silicon nitride layer 151, a silicon oxide layer 152, a silicon nitride layer 153, and a silicon oxide layer 154. The structure of the wiring pattern is similar to that of the second wiring layer WL2 to fourth wiring layers WL4.

Similar to the interlayer insulating film for the fifth wiring layer WL5, the interlayer insulating films for sixth and seventh wiring layers WL6 and WL7 are made of lamination layers constituted of silicon nitride layers 161 and 171, silicon oxide layers 162 and 172, organic insulating layers 163 and 173 and silicon oxide layers 164 and 174. The structure of the wiring pattern is similar to that of the fifth wiring layer WL5.

Upper wiring layers have a broad pitch between wiring lines and a coarse wiring density. Therefore, there is a low necessity of using a low dielectric constant insulating layer to reduce parasitic capacitance between wiring lines. From this reason, the fifth to seventh wiring layers do not use the organic insulating layer to improve the reliability of the interlayer insulating film.

The uppermost eighth wiring layer WL8 has the structure specific to it. A lower insulating layer is constituted of a silicon nitride layer 181 and a silicon oxide layer 182, and a via portion is constituted of a barrier metal layer B81 and a tungsten layer V8.

A wiring layer used also as pads is constituted of a TiN layer B82, an aluminum layer W8 and a TiN layer B83 and formed above the via portion. Instead of aluminum, Cu may be used. A silicon oxide layer 183 and a silicon nitride layer 190 are formed covering the uppermost wiring layer.

In the structure shown in FIG. 13, the auxiliary barrier metal layer is buried in the wiring pattern of all of the first wiring layer WL1 to seventh wiring layer WL7 to thereby suppress the generation of voids. The structure of the interlayer insulating film is different in the upper wiring layers excepting the lower wiring layers and the upper most wiring layer.

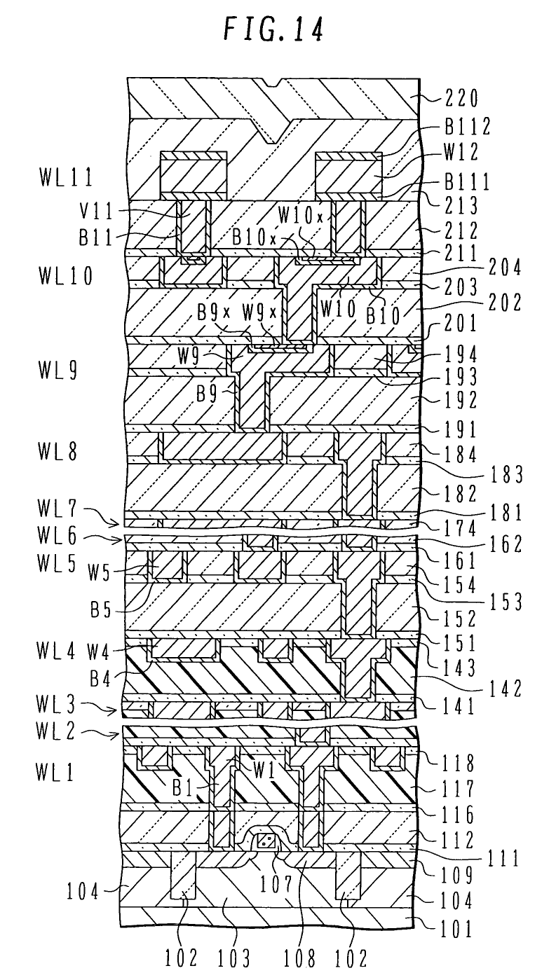

FIG. 14 shows another example of the structure of a semiconductor integrated circuit device having a multi-layer wiring structure. The structure of MOS transistors formed on the semiconductor substrate and the structure of conductive plug leads for source/drain are similar to those shown in FIG. 13.

On a PSG layer 112, a lamination layer constituted of an SiC layer 116, an organic insulating layer 117 and an SiC layer 118 are formed, and a first wiring layer WL1 is constituted of a barrier metal layer B1 and a copper wiring layer W1. An auxiliary barrier metal layer is not used.

A second wiring layer WL2 to a fourth wiring layer WL4 have the structure similar to that of the first wiring layer WL1. The fourth wiring layer WL4 will be described by way of example. An interlayer insulting film is constituted of an SiC layer 141, an organic insulating layer 142 and an SiC layer 143. A dual damascene wiring is constituted of a barrier metal layer B4 and a copper layer W4, and an auxiliary barrier metal layer is not disposed.

A fifth wiring layer WL5 to an eighth wiring layer WL8 have the similar structure. The fifth wiring layer WL5 will be described by way of example. An interlayer insulating film is constituted of an SiC layer 151, a silicon oxycarbide (SiOC) layer 152, an SiC layer 153 and a silicon oxycarbide layer 154. A dual damascene wiring is constituted of a barrier layer B5 and a copper wiring layer W5, and an auxiliary barrier metal layer is not disposed.

In a ninth wiring layer WL9, buried in an interlayer insulating film constituted of an SiC layer 191, a silicon oxide layer 192, an AiC layer 193 and a silicon oxide layer 194, is a dual damascene wiring constituted of a barrier metal layer B9, a copper wiring layer W9, an auxiliary barrier metal layer B9x and an auxiliary copper wiring layer W9x.

A tenth wiring layer WL10 has the structure similar to that of the ninth wiring layer WL9. Buried in an interlayer insulating film constituted of an SiC layer 201, a silicon oxide layer 202, an AiC layer 203 and a silicon oxide layer 204, is a dual damascene wiring constituted of a barrier metal layer B10, a copper wiring layer W10, an auxiliary barrier metal layer B10x and an auxiliary copper wiring layer W10x. The uppermost wiring layer WL11 has the structure similar to that of the uppermost wiring layer shown in FIG. 13. A lamination layer is constituted of an SiC layer 211 and a silicon oxide layer 212, and in this lamination layer, a via conductor constituted of a TiN barrier metal layer B11 and a W wiring layer W11 is buried. Formed above the via conductor are a TiN layer B111, a main wiring layer W12 made of aluminum or aluminum alloy containing copper, and the uppermost wiring layer to be used also as bonding pads and made of a TiN upper barrier metal layer B112. A silicon oxide layer 213 and a silicon nitride layer 220 are formed covering this wiring layer.

With the structure shown in FIG. 14, the lamination structure of the interlayer insulating layers change at three steps from the lower to upper layers, and the effective dielectric constant is lower as the layer is lower. The lower wiring is highly dense, and it is preferable to lower the dielectric constant of the interlayer insulating film in order to reduce parasitic capacitance.

The present invention has been described in connection with the preferred embodiments. The invention is not limited only to the above embodiments. For example, the composition of HfAlO is not limited to Hf_{0.8}Al_{0.2}O. Other metal oxides may be used.

It will be apparent to those skilled in the art that other various modifications, improvements, combinations, and the like can be made. The present invention is applicable to a semiconductor integrated circuit device having fine IG-FETs and the like.

1. A semiconductor device comprising:
a silicon substrate;
a silicon oxide layer formed on a surface of said silicon substrate;
a first oxide layer formed above said silicon oxide layer, said first oxide layer being made of a high dielectric constant film having a dielectric constant higher than silicon oxide;
a first nitride layer formed above said first oxide layer, said first nitride layer being made of nitride having an oxygen intercepting capability; and
a gate electrode formed above said first nitride layer.

2. The semiconductor device according to claim 1, wherein said first oxide layer comprises oxide of any one of Hf, Ti, Ta, Zr, Y, W, Al and La.

3. The semiconductor device according to claim 1, wherein said first oxide layer comprises a hafnium oxide layer, and said first nitride layer comprises an aluminum nitride layer or a silicon nitride layer.

4. The semiconductor device according to claim 3, wherein said first oxide layer also includes Al or Si.

5. The semiconductor device according to claim 3, wherein said first oxide layer also comprises a hafnium oxynitride layer or an aluminum oxynitride layer formed on at least one of upper and lower surfaces of said hafnium oxide layer.

6. The semiconductor device according to claim 1, wherein said first oxide layer comprises a hafnium oxynitride layer or an aluminum oxynitride layer.

7. The semiconductor device according to claim 1, wherein said first nitride layer contains Hf.

8. The semiconductor device according to claim 7, wherein said first nitride layer contains Hr more than Al.

9. The semiconductor device according to claim 3, wherein said first nitride layer contains Si.

10. The semiconductor device according to claim 1, wherein said first nitride layer contains oxygen.

11. The semiconductor device according to claim 1, wherein said first nitride layer includes a nitride layer containing aluminum nitride and a nitride layer containing silicon.

12. The semiconductor device according to claim 1, wherein said first nitride layer comprises a hafnium oxynitride layer or an aluminum oxynitride layer.

13. The semiconductor device according to claim 1, further comprising a second nitride layer disposed between said first oxide layer and said silicon oxide layer.

14. The semiconductor device according to claim 13, wherein said second nitride layer contains any one of Hf and Si.

15. The semiconductor device according to claim 13, wherein said second nitride layer contains also oxygen.

16. The semiconductor device according to claim 1, wherein said gate electrode is made of oxygen supplying material.

17. A method of manufacturing a semiconductor device comprising a silicon substrate, a silicon oxide layer formed on a surface of said silicon substrate; and a first oxide layer made of a high dielectric constant film having a dielectric constant higher than that of silicon oxide, comprising the steps of:
(a) forming said first oxide layer having a high dielectric constant above said silicon oxide layer;
(b) forming a first nitride layer above said first oxide layer, said first nitride layer being made of nitride having an oxygen intercepting capability; and
(c) forming a gate electrode above said first nitride layer.

18. The manufacture method for a semiconductor device according to claim 17, further comprising the step of:
(d) forming said silicon oxide layer by (HCl+H₂O₂+H₂O) process.

19. The manufacture method for a semiconductor device according to claim 17, wherein said first nitride layer contains Hf.

20. The manufacture method for a semiconductor device according to claim 19, wherein Al content contained in said first nitride layer is smaller than Hf content.

21. The manufacture method for a semiconductor device according to claim 17, wherein said gate electrode is made of oxygen supplying material.

22. The manufacture method for a semiconductor device according to claim 17, wherein said step (a) forms a hafnium oxide layer by organic metal vapor deposition, and the method further comprises the step of:
(e) after said step (a), executing annealing at 600° C. to 1100° C.

23. The manufacture method for a semiconductor device according to claim 22, wherein said step (a) or (b) forms a hafnium oxynitride layer or an aluminum oxynitride layer.

24. A semiconductor device comprising:
a silicon substrate;
a silicon oxide layer formed on a surface of said silicon substrate;
a high dielectric constant insulating layer including a first oxide layer formed above said silicon oxide layer, a second oxide layer formed on said first oxide layer and a third oxide layer formed on said second oxide layer, said first and third oxide layers having an oxygen diffusion coefficient smaller than that of said second oxide layer; and
a gate electrode formed above said high dielectric constant insulating layer.

25. The semiconductor device according to claim 24, wherein said second oxide layer contains any one of HfO), TiO, TaO, ZrO, YO, WO, AlO and LaO.

26. The semiconductor device according to claim 25, wherein said second oxide layer is made of HfO or any one of HfAlO, HfSiO, HfAISiO, HfAION, HfSiON and HfAISiON.

27. The semiconductor device according to claim 24, wherein said first and third oxide layers contain AlO.

28. The semiconductor device according to claim 27, wherein said first and third oxide layers contain also any one of HfO, TiO, TaO, ZrO, YO and WO.

29. The semiconductor device according to claim 24, wherein said second oxide layer has trap levels lower than said first and third oxide layers.

30. The semiconductor device according to claim 24, wherein said second oxide layer is an HfAlO layer and said first and third oxide layers are AlO layers.

31. The semiconductor device according to claim 24, wherein a thickness of said second oxide layer is 1 nm to 5 nm.

32. The semiconductor device according to claim 24, wherein a thickness of said first oxide layer or said third oxide layer is 0.3 nm to 1 nm.

33. The semiconductor device according to claim 24, wherein a thickness of said second oxide film is in a range of 1 nm to 5 nm and a thickness of said first and third oxide layers is in a range of 0.3 nm to 1 nm.

34. A method of manufacturing a semiconductor device comprising the steps of:
(a) removing a natural oxide film on a surface of a silicon substrate by wet etching;
(b) forming an underlying silicon oxide layer on the surface of the silicon substrate with the natural oxide film being removed, by a chemical process;
(c) forming a first high dielectric constant oxide layer on the underlying silicon oxide layer by CVD at a first oxygen supply rate;
(d) forming a second high dielectric constant oxide layer on the first high dielectric constant oxide layer by CVD at a second oxygen supply rate higher than the first oxygen supply rate;
(e) forming a third high dielectric constant oxide layer on the second high dielectric constant oxide layer by CVD at a third oxygen supply rate lower than the second oxygen supply rate; and
forming a gate electrode on the third high dielectric constant oxide layer by using oxidizable material.

35. The method of manufacturing a semiconductor device according to claim 34, wherein said step (b) executes (HCl+H₂O₂+H₂O) process.

36. The method of manufacturing a semiconductor device according to claim 34, wherein at least one of said steps (c) and (e) deposit a layer containing AlO.

37. The method of manufacturing a semiconductor device according to claim 34, wherein said step (d) deposits an HfAlO layer and at least one of said steps (c) and (e) deposits an AlO layer or an HfAlO layer having a high Al composition.

38. The method of manufacturing a semiconductor device according to claim 34, wherein said step (d) is executed without forming substantially a new reaction layer under said first high dielectric constant oxide layer.

39. The method of manufacturing a semiconductor device according to claim 34, wherein said step (f) is executed without forming substantially a new reaction layer under said third high dielectric constant oxide layer.

40. The method of manufacturing a semiconductor device according to claim 39, wherein said process (f) deposits a silicon layer or an aluminum layer.

41. The method of manufacturing a semiconductor device according to claim 34, wherein said steps (c) and (e) are executed at a same total flow rate as a total flow rate of growth gasses of said step (d) and at a half of or a smaller oxygen supply amount than that of said step (d).
